(19) United States
(12) Patent Application Publication
(10) Pub. No.: US 2026/0371992 A1
(43) Pub. Date: Nov. 19, 2026

(54) DUAL-TRACK DIE BONDING DEVICE AND A DIE BONDING METHOD

(71) Applicant: MICROVIEW INTELLIGENT PACKAGING TECHNOLOGY (SHENZHEN) CO., LTD, SHENZHEN (CN)

(72) Inventor: XIONGHUI LIAO, SHENZHEN (CN)

(21) Appl. No.: 19/570,276

(22) Filed: Mar. 18, 2026

(30) Foreign Application Priority Data
May 19, 2025 (CN) 202510639702.2

(51) Int. Cl. H10P 72/00

(52) U.S. Cl. CPC H10P 72/0446

(57) ABSTRACT

A dual-track die bonding device and a die bonding method are provided. The dual-track die bonding device includes a carrying platform, a movable die bonding stage assembly, and a movable transfer stage assembly disposed on the carrying platform. The carrying platform defines a mounting area, a dispensing area, and a loading area. The dispensing area and the loading area are adjacent to each other. The dispensing area and the loading area are defined on a same side of the mounting area. The movable die bonding stage assembly includes a first track, a second track, a first die bonding stage, and a second die bonding stage. The first die bonding stage is slidably connected to the first track, and the second die bonding stage is slidably connected to the second track. The first track and the second track respectively extend from the dispensing area to the mounting area.

### TECHNICAL FIELD

The present disclosure relates to a technical field of semiconductor mounting devices, and in particular to a dual-track die bonding device and a die bonding method.

### BACKGROUND

In a field of semiconductor mounting devices, a die bonding process involves bonding a chip onto a specific position on a substrate. Conventional methods commonly involve performing a one-time adhesive dispensing or dipping process across the entire substrate, followed by chip mounting. However, for substrates requiring the mounting of a large number of chips, the conventional methods present significant defects. For instance, due to a potentially long time interval between an initial dispensing and a completion of mounting of all chips, some of adhesive may begin to solidify during a waiting period, which negatively affects both mounting quality and overall efficiency.

### SUMMARY

To address a technical problem that conventional die bonding devices are unable to meet a demand for mounting a large number of chips on a same substrate, the present disclosure provides a dual-track die bonding device and a die bonding method.

To address the technical problem, the present disclosure provides a dual-track die bonding device. The dual-track die bonding device comprises a carrying platform, a movable die bonding stage assembly disposed on the carrying platform, and a movable transfer stage assembly disposed on the carrying platform. The carrying platform defines a mounting area, a dispensing area, and a loading area. The dispensing area and the loading area are adjacent to each other. The dispensing area and the loading area are defined on a same side of the mounting area. The movable die bonding stage assembly comprises a first track, a second track, a first die bonding stage, and a second die bonding stage. The first die bonding stage is slidably connected to the first track, and the second die bonding stage is slidably connected to the second track. The first track and the second track respectively extend from the dispensing area to the mounting area. In a working state, the first die bonding stage and the second die bonding stage work alternately in the mounting area and the dispensing area. The movable transfer stage assembly comprises a third track and a first transfer stage slidably connected to the third track. The third track extends from the loading area to the mounting area, and the first transfer stage is movable back and forth between the loading area and the mounting area via the third track.

Optionally, a first robotic arm, a first material stage, and a dispensing stage assembly are disposed within the dispensing area. The first robotic arm is movable within the dispensing area. The first robotic arm is configured to transport first materials between the first material stage and the movable die bonding stage assembly, or perform a dispensing operation between the dispensing stage assembly and the movable die bonding stage assembly;

A second robotic arm and a second material stage are disposed within the loading area. The second robotic arm is movable within the loading area. When the first transfer stage is located within the loading area, the second robotic arm is configured to transport the second materials between the second material stage and the first transfer stage.

Optionally, the first track, the second track, and the third track are spaced apart and parallel to each other. The first track and the second track are located on one side of the dispensing area close to the loading area. The third track is located on one side of the loading area close to the dispensing area.

Optionally, a first upward-looking module is disposed within the loading area, and a second upward-looking module is disposed within the mounting area. The first upward-looking module is located between the second material stage and the third track. The second upward-looking module is located between the third track and the movable die bonding stage assembly. Shooting accuracy of the second upward-looking module is greater than a shooting accuracy of the first upward-looking module.

Optionally, a nozzle rack assembly is disposed within the mounting area. The nozzle rack assembly is located at one end of the third track and spans above the third track.

Optionally, a third material stage and a second transfer stage are disposed within the mounting area. The third material stage and the second transfer stage are respectively disposed on two sides of the third track. The second transfer stage is located between the third track and the movable die bonding stage assembly. The second transfer stage is close to the second upward-looking module.

Optionally, a standard positioning piece is disposed within the mounting area. A top surface of the standard positioning piece defines a positioning point. The standard positioning piece is disposed between the third track and the movable die bonding stage assembly.

Optionally, a gantry assembly is disposed within the mounting area. The gantry assembly comprises two support columns and a beam rail. The two support columns are located on two opposite sides of the mounting area. The beam rail is slidably disposed between the two support columns. A main bonding head is disposed on the beam rail. A replaceable nozzle and a downward-looking module are disposed on the main bonding head.

Optionally, an expansion component is disposed on the main bonding head. The expansion component comprises at least one expansion module. The at least one expansion module comprises auxiliary bonding heads or a dispensing component.

The present disclosure further provides a die bonding method applied to the dual-track die bonding device mentioned above. The die bonding method comprises:
performing, within the dispensing area, the dispensing operation on a substrate placed on the first die bonding stage or a substrate placed on the second die bonding stage via the first robotic arm, and transporting a dispensed substrate into the mounting area; wherein only a partial area of each substrate is dispensed each time the dispensing operation is performed;
transporting a chip onto the first transfer stage via the second robotic arm within the loading area, and moving the first transfer stage to the mounting area via the third track;
mounting the chip from the first transfer stage alternately onto the dispensed substrate placed on the first die bonding stage or the disposed substrate placed on the second die bonding stage via the main bonding head within the mounting area to complete chip mounting; and
performing at least two rounds of dispensing and chip mounting on each substrate by moving the movable die bonding stage assembly back and forth between the mounting area and the dispensing area.

When the first die bonding stage is located within the mounting area, and the second die bonding stage is located within the dispensing area, and when the first die bonding stage is located within the dispensing area, the second die bonding stage is located within the mounting area, so that the dispensing operation and a chip mounting operation are performed synchronously on the first die bonding stage and the second die bonding stage respectively.

Compared with the prior art, the dual-track die bonding device and the die bonding method of the present disclosure have following characteristics.

The dual-track die bonding device provided by the embodiment of the present disclosure aims to solve a problem of adhesive solidification in conventional die bonding processes. By introducing the first die bonding stage and the second die bonding stage that work alternately, dispensing is performed only on a partial area of each substrate during each dispensing operation, followed immediately by chip mounting on the partial area, thereby ensuring mounting quality and efficiency. Specifically, the carrying platform serves as a main body to support modules or components required for die bonding. Three functional areas, which are respectively the mounting area, the dispensing area, and the loading area, are defined on the carrying platform. Close proximity between the three functional areas simplifies material transfer paths. Furthermore, the three functional areas are disposed adjacently without overlapping, allowing the three functional areas to independently complete their respective mounting, dispensing, and loading operations while transporting materials through the movable die bonding stage assembly and the movable transfer stage assembly. Each area focuses on a single task, preventing mutual interference between different processes. The first die bonding stage and the second die bonding stage slide alternately on the first track and the second track, allowing the first die bonding stage and the second die bonding stage to work interchangeably between the dispensing area and the mounting area. That is, while one of the two die bonding stages is operated in the dispensing area, the other one of the two die bonding stages is operated in the mounting area. Upon completion, the two die bonding stages swap areas via their respective tracks. Such configurations ensure that the chip is immediately mounted on a corresponding substrate after partial dispensing is performed on the corresponding substrate, shortening a time interval between dispensing and mounting. An alternating operation further ensures that the dispensing area and the mounting area function simultaneously, eliminating idle waiting and productivity waste.

In the embodiment of the present disclosure, the first robotic arm and the second robotic arm that are independently operated are respectively disposed within the dispensing area and the loading area. Both areas and execution modules are partitioned, allowing the dispensing operation and the loading operation to be performed synchronously without mutual interference, thus avoiding potential issues caused by process crossover, such as material mixing or operational conflicts. The first robotic arm and the second robotic arm are respectively configured to perform the dispensing operation and the loading operation and are movable freely within their respective areas without being affected by the other. Such an independent control design allows each robotic arm to focus on its own task, improving operational precision and response speed. Since the dispensing operation and the loading operation are allowed to be performed simultaneously, the entire die bonding process achieves parallel processing; loading is not delayed by dispensing, and vice versa. Therefore, chips are always ready for a mounting phase, and each substrate is dispensed in a timely manner, reducing unnecessary waiting time. In this way, it not only accelerates production speed but also enables the dual-track die bonding device to complete more tasks in a shorter timeframe.

In the embodiment of the present disclosure, a certain distance is maintained between the three tracks (i.e., the first track, the second track, and the third track), which prevents mutual interference between the movable assemblies on different tracks and ensures independence and high efficiency of each process. A parallel arrangement of the first track, the second track, and the third track simplifies a path planning for the second robotic arm and other transport tools, reducing complexity and improving operational efficiency. Further, the parallel arrangement of the three tracks close to their respective areas ensures that a distance for moving each of the chips onto a corresponding substrate during a chip mounting process is shorter. A shorter moving distance means that the second robotic arm or the transport tools are able to respond more quickly to operational commands, reducing waiting time and periodic delays. Furthermore, the shorter moving distance reduces deviations in chip mounting positions that may be caused by long-distance handling, thereby improving the accuracy of chip mounting, which is particularly important in semiconductor manufacturing processes with high precision requirements.

In the embodiment of the present disclosure, by providing the first upward-looking module and the second upward-looking module to perform two calibrations of the chips during loading and mounting processes, it is ensured that each of the chips is accurately bonded to the corresponding substrate with high precision. Specifically, the first upward-looking module is mainly configured to capture images when one of the chips is transferred from the second material stage to the first transfer stage on the third track, ensuring a basic orientation of each of the chips is correct and suitable for preliminary adjustment of a position of each of the chips. The second upward-looking module is configured for high-precision imaging just before each of the chips is mounted onto the corresponding substrate to ensure a final position of each of the chips is precise and error-free. Due to the higher shooting accuracy of the second upward-looking module, the second upward-looking module is able to capture finer positional deviations, thereby achieving more delicate adjustments. By first using the first upward-looking module with a low precision for coarse calibration and then using the second upward-looking module with a high precision for fine calibration, a process of gradually optimizing the position of each of the chips is realized. The step-by-step calibration method not only improves accuracy of calibration but also saves time, avoiding complexity and increased costs associated with one-time high-precision calibration.

In the embodiment of the present disclosure, the nozzle rack assembly is allowed to be equipped with different types of nozzles, making it convenient for the main bonding head to replace nozzles to adapt to chips of various sizes and shapes, which enhances versatility and flexibility of the dual-track die bonding device. The nozzle rack assembly is disposed at the end of the third track and spans above the third track, so that a vertical space is fully utilized to prevent the nozzle rack assembly from occupying additional horizontal area, making an overall layout of the dual-track die bonding device compact. When a nozzle needs to be replaced, since the nozzle rack assembly is already located at the end of the third track, the nozzle rack assembly is able to immediately move to a position of the first transfer stage after a replacement of the nozzle is completed without requiring additional long-distance movement, significantly shortening preparation time. Even in cases of frequent replacements of the nozzles, a short distance between the nozzle rack assembly and the first transfer stage ensures that a first picking operation performed by the nozzle rack assembly after each replacement is completed quickly and accurately, guaranteeing the precision of chip mounting.

In the embodiment of the present disclosure, the third material stage serves as a storage and supply spot for multiple types of chips, providing a stable and sufficient supply of raw materials for the mounting process. The third material stage is capable of supporting the chips of different specifications and quantities, adapting to diversified production requirements. The third material stage and the second transfer stage are respectively disposed on two sides of the third track, preventing crossover of material transfer paths and minimizing the distance from the first transfer stage and the second transfer stage to the movable die bonding stage assembly. Being disposed close to the second upward-looking module, the second transfer stage allows for fine calibration under high-precision imaging, ensuring each of the chips is in the optimal position before entering a mounting step, thereby improving a success rate and quality of chip mounting.

In the embodiment of the present disclosure, the positioning point serves as a calibration reference for the main bonding head, providing a precise reference position. Through the positioning point on the standard positioning piece, high-precision calibration of the main bonding head and other related components is achieved, ensuring that each of the chips is accurately bonded to a designated position on the corresponding substrate, which greatly enhances the quality and reliability of chip mounting. The standard positioning piece is located between two key components, fully utilizing the space within the mounting area and avoiding an occupation of additional space, making the overall layout of the dual-track die bonding device compact and reasonable.

In the embodiment of the present disclosure, the two support columns provide a stable foundation for the gantry assembly, ensuring stability during operation and reducing vibrations caused by mechanical movement or external factors. The beam rail is slidable along the two support columns, enabling the main bonding head to move freely within the mounting area, covering a larger workspace and adapting to the mounting requirements of substrates and chips of various specifications and positions. The main bonding head is slidable on the beam rail, achieving flexible movement within the mounting area and allowing it to quickly reach any required position for the chip mounting operation. The replaceable nozzle is configured to accurately pick and place each of the chips, ensuring each of the chips is precisely bonded to the designated position on the corresponding substrate. The downward-looking module is able to capture images of the position of each of the chips and each substrate in real-time during the mounting process, ensuring every chip is in the optimal position before each mounting action to prevent misalignment or offset. Through the stable support provided by the gantry assembly and the high-precision visual detection of the downward-looking module, the accuracy and consistency of each chip mounting operation are ensured, significantly improving mounting quality and reliability.

In the embodiment of the present disclosure, the expansion component provides physical space and interfaces for adding additional components, allowing the dual-track die bonding device to be flexibly configured according to actual production needs, which enhances versatility and adaptability of the dual-track die bonding device. The at least one expansion module is primarily configured to achieve multi-chip mounting, is capable of picking up a plurality of chips at once and accurately placing the plurality of chips onto designated positions on a corresponding substrate, significantly improving mounting efficiency. Since the at least one expansion module comprises nozzle modules simultaneously, a need for frequent replacement of the nozzles is reduced, saving time and costs while improving overall work efficiency.

The embodiment of the present disclosure further provides the die bonding method applied to the aforementioned die bonding device, which therefore possesses the same effects as the dual-track die bonding device described above, and is not reiterated herein.

### BRIEF DESCRIPTION OF DRAWINGS

FIG. 1 is a schematic diagram showing a layout of a dual-track die bonding device according to a first embodiment of the present disclosure.

FIG. 2 is a schematic diagram of a movable transfer stage assembly according to the first embodiment of the present disclosure.

FIG. 3 is another schematic diagram of the movable transfer stage assembly according to the first embodiment of the present disclosure.

FIG. 4 is a partial schematic diagram of a movable die bonding stage assembly according to the first embodiment of the present disclosure.

FIG. 5 is a schematic diagram showing a layout of a dispensing area of the dual-track die bonding device according to the first embodiment of the present disclosure.

FIG. 6 is a schematic diagram showing a layout of a loading area of the dual-track die bonding device according to the first embodiment of the present disclosure.

FIG. 7 is a schematic diagram showing a layout of a mounting area of the dual-track die bonding device according to the first embodiment of the present disclosure.

FIG. 8 is a schematic diagram of a gantry assembly of the dual-track die bonding device according to the first embodiment of the present disclosure.

In the drawings: 100—dual-track die bonding device; 1—carrying platform; 11—mounting area; 111—gantry assembly; 1111—support column; 1112—beam rail; 1113—main bonding head; 1114—replaceable nozzle; 1115—downward-looking module; 1116—expansion component; 1117—expansion module; 112—second upward-looking module; 113—nozzle rack assembly; 114—third material stage; 115—second transfer stage; 116—standard positioning piece; 12—dispensing area; 121—first robotic arm; 122—first material stage; 123—dispensing stage assembly; 13—loading area; 131—second robotic arm; 132—second material stage; 133—first upward-looking module; 2—movable die bonding stage assembly; 21—first track; 211—linear motor; 212—drag chain; 22—second track; 23—first die bonding stage; 24—second die bonding stage; 3—movable transfer stage assembly; 31—third track; 32—first transfer stage.

### DETAILED DESCRIPTION

In order to make objectives, technical solutions, and advantages of the present disclosure clearer, the following further describes the present disclosure in detail with reference to accompanying drawings and embodiments. It should be understood that the specific embodiments described here are only used to explain the present disclosure, but not to limit the present disclosure.

In the embodiment of the present disclosure, it should be understood that “B corresponding to A” means that B is associated with A, and B can be determined based on A. However, it should also be understood that determining B based on A does not mean determining B solely based on A; B may also be determined based on A and/or other information.

Reference herein to “embodiment” or “implement” means that a particular feature, structure, or characteristic described in connection with one embodiment or one implement may be comprised in at least one embodiment of the present disclosure. The appearances of the “embodiment” in various positions in the specification are not necessarily referring to the same embodiment, and are not independent or alternative embodiments mutually exclusive of other embodiments. Those skilled in the art explicitly and implicitly understand that the embodiments described herein may be combined with other embodiments.

It should be understood that the order of the steps in the above-mentioned embodiments is not necessarily the order of execution, and the execution order of the steps should be determined by function and inherent logic, which should not be regarded as limitations to the implementation processes of the embodiment of the present disclosure.

The flowcharts and block diagrams in the accompanying drawings illustrate the architecture, functionality, and operation of possible implementations of systems, methods, and computer program products according to various embodiments of the present disclosure. In this regard, each block in a flowchart or block diagram may represent a module, segment, or portion of code containing one or more executable instructions for implementing a specified logical function. It should also be noted that in some alternative implementations, the functions indicated in the blocks may occur in a different order than those indicated in the drawings. For example, two consecutively indicated blocks may actually be executed substantially in parallel, or they may sometimes be executed in reverse order, depending on the functions involved. It is particularly important to note that each block in a block diagram and/or flowchart, and combinations of blocks in block diagrams and/or flowcharts, can be implemented using a dedicated hardware-based system that performs the specified function or operation, or using a combination of dedicated hardware and computer instructions.

In semiconductor packaging and assembly processes, die bonding is a widely used chip mounting method, which typically refers to a process of using adhesives to fix chips onto a carrier (such as a substrate).

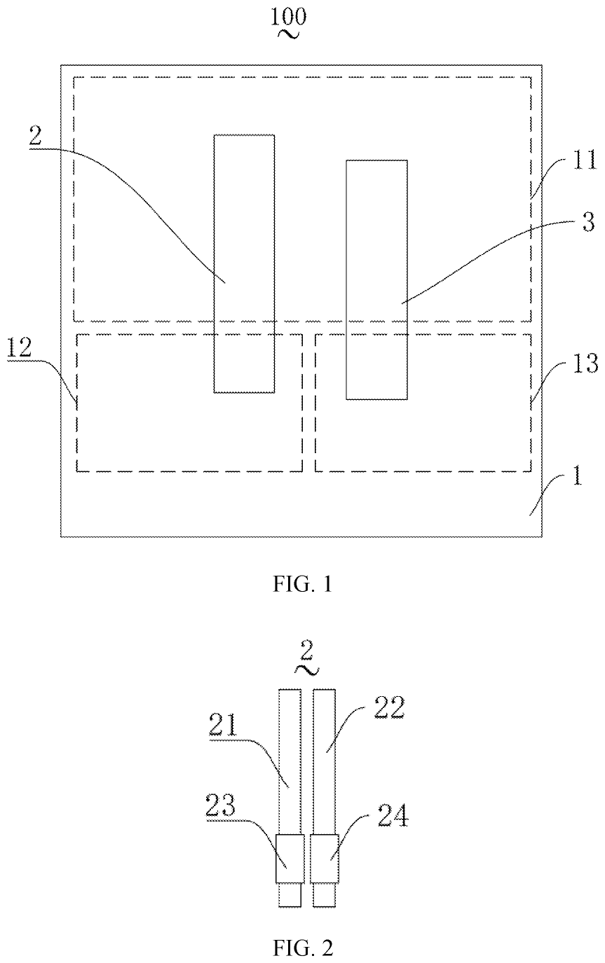

As shown in FIGS. 1-3, a first embodiment of the present disclosure provides a dual-track die bonding device 100. The dual-track die bonding device 100 comprises a carrying platform 1. The carrying platform 1 defines a mounting area 11, a dispensing area 12, and a loading area 13. The dispensing area 12 and the loading area 13 are adjacent to each other. The dispensing area 12 and the loading area 13 are defined on a same side of the mounting area 11.

The dual-track die bonding device 100 further comprise a movable die bonding stage assembly 2 disposed on the carrying platform 1, and a movable transfer stage assembly 3 disposed on the carrying platform 1. The movable die bonding stage assembly 2 comprises a first track 21, a second track 22, a first die bonding stage 23, and a second die bonding stage 24. The first die bonding stage 23 is slidably connected to the first track 21, and the second die bonding stage 24 is slidably connected to the second track 22. The first track 21 and the second track 22 respectively extend from the dispensing area 12 to the mounting area 11. In a working state, the first die bonding stage 23 and the second die bonding stage 24 work alternately in the mounting area 11 and the dispensing area 12.

The movable transfer stage assembly 3 comprises a third track 31 and a first transfer stage 32 slidably connected to the third track 31. The third track 31 extends from the loading area 13 to the mounting area 11, and the first transfer stage 32 is movable back and forth between the loading area 13 and the mounting area 11 via the third track 31.

The dual-track die bonding device 100 provided by the embodiment of the present disclosure aims to solve a problem of adhesive solidification in conventional die bonding processes. By introducing the first die bonding stage 23 and the second die bonding stage 24 that work alternately, dispensing is performed only on a partial area of each substrate during each dispensing operation, followed immediately by chip mounting on the partial area, thereby ensuring mounting quality and efficiency. Specifically, the carrying platform 1 serves as a main body to support modules or components required for die bonding. Three functional areas, which are respectively the mounting area 11, the dispensing area 12, and the loading area 13, are defined on the carrying platform 1. Close proximity between the three functional areas simplifies material transfer paths. Furthermore, the three functional areas are disposed adjacently without overlapping, allowing the three functional areas to independently complete their respective mounting, dispensing, and loading operations while transporting materials through the movable die bonding stage assembly 2 and the movable transfer stage assembly 3. Each area focuses on a single task, preventing mutual interference between different processes. The first die bonding stage 23 and the second die bonding stage 24 slide alternately on the first track 21 and the second track 22, allowing the first die bonding stage 23 and the second die bonding stage 24 to work interchangeably between the dispensing area 12 and the mounting area 11. That is, while one of the two die bonding stages is operated in the dispensing area 12, the other one of the two die bonding stages is operated in the mounting area 11. Upon completion, the two die bonding stages swap areas via their respective tracks. Such configurations ensure that the chip is immediately mounted on a corresponding substrate after partial dispensing on the corresponding substrate, shortening a time interval between dispensing and mounting. An alternating operation further ensures that the dispensing area 12 and the mounting area 11 function simultaneously, eliminating idle waiting and productivity waste.

As shown in FIG. 1, in one embodiment, an overall arrangement of the mounting area 11, the dispensing area 12, and the loading area 13 is roughly rectangular. In a top plan view, the mounting area 11 is located in a middle upper region of the carrying platform 1, the dispensing area 12 is located in a lower left region of the carrying platform 1, and the loading area 13 is located in a lower right region of the carrying platform 1, with each of the three areas being arranged in a roughly rectangular shape. That is, an overall shape of the three areas consists of a large rectangle with two smaller rectangles arranged side-by-side below it, so that an outer frame of the carrying platform 1 after the overall arrangement is rectangular. It is understood that the rectangular arrangement fully utilizes an available area of the carrying platform 1, ensuring that each of the functional areas is arranged compactly and orderly, making an overall layout of the carrying platform 1 concise and organized.

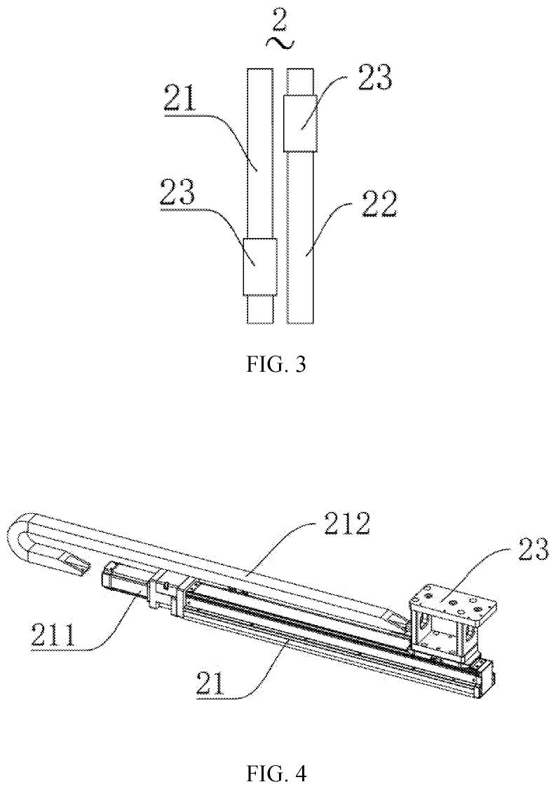

As shown in FIGS. 2-3, the first die bonding stage 23 is slidable on the first track 21, and the second die bonding stage 24 is slidable on the second track 22. Sliding of the first die bonding stage 23 and the second die bonding stage 24 is independently controlled. In the working state, when the first die bonding stage 23 is located at an end of the first track 21 close to the dispensing area 12, then the second die bonding stage 24 is located at an end of the second track 22 close to the mounting area 11, and vice versa.

As shown in FIG. 4, the movable die bonding stage assembly 2 further comprises a linear motor 211 disposed on the first track 21. The linear motor 211 is configured to drive the first die bonding stage 23 to move on the first track 21. The movable die bonding stage assembly 2 further comprises a drag chain 212 disposed close to the first track 21. The drag chain 212 is configured to accommodate working cables of the first die bonding stage 23. The drag chain 212 is parallel to the first track 21.

It is understood that the linear motor 211 has high-precision position control capabilities, enabling the first die bonding stage 23 to be accurately moved to a designated position, ensuring consistency and accuracy of each operation. The drag chain 212 provides physical protection for the working cables of the first die bonding stage 23, preventing the working cables from being damaged due to frequent movement and extending the service life of the working cables. The drag chain 212 is arranged parallel to the first track 21 to ensure that the working cables move synchronously with the first die bonding stage, reduces potential conflicts between the working cables and other components, and avoids interference during operation. Through a smooth motion driven by the linear motor 211 and a protection of the drag chain 212 on the working cables, influence of mechanical vibration and other external factors is reduced, thereby further guaranteeing stability of the dual-track die bonding device and mounting quality of chips.

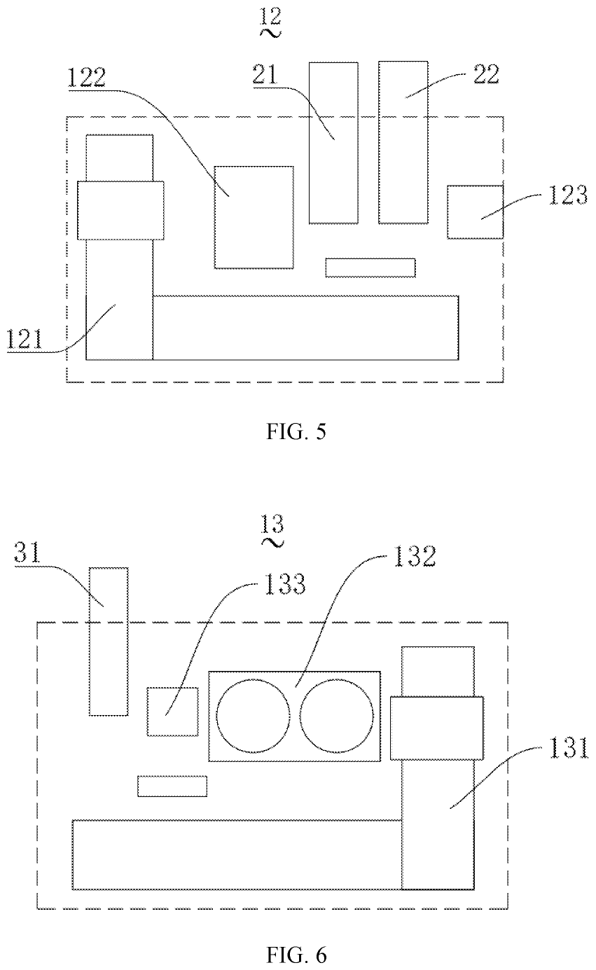

As shown in FIGS. 5-6, in one embodiment, a first robotic arm 121, a first material stage 122, and a dispensing stage assembly 123 are disposed within the dispensing area 12. The first robotic arm 121 is movable within the dispensing area 12. The first robotic arm 121 is configured to transport first materials between the first material stage 122 and the movable die bonding stage assembly 2, or perform the dispensing operation between the dispensing stage assembly 123 and the movable die bonding stage assembly 2. A second robotic arm 131 and a second material stage 132 are disposed within the loading area 13. The second robotic arm 131 is movable within the loading area 13. When the first transfer stage 32 is located within the loading area 13, the second robotic arm 131 is configured to transport second materials between the second material stage 132 and the first transfer stage 32.

It is understood that, in the embodiment of the present disclosure, the first robotic arm 121 and the second robotic arm 131 that are independently operated are respectively disposed within the dispensing area 12 and the loading area 13. Both areas and execution modules are partitioned, allowing the dispensing operation and the loading operation to be performed synchronously without mutual interference, thus avoiding potential issues caused by process crossover, such as material mixing or operational conflicts. The first robotic arm 121 and the second robotic arm 131 are respectively configured to perform the dispensing operation and the loading operation and are movable freely within their respective areas without being affected by the other. Such an independent control design allows each robotic arm to focus on its own task, improving operational precision and response speed. Since the dispensing operation and the loading operation are allowed to be performed simultaneously, the entire die bonding process achieves parallel processing; loading is not delayed by dispensing, and vice versa. Therefore, the chips are always ready for a mounting phase, and each substrate is dispensed in a timely manner, reducing unnecessary waiting time. In this way, it not only accelerates production speed but also enables the dual-track die bonding device 100 to complete more tasks in a shorter timeframe.

As shown in FIG. 5, in one embodiment, the first material stage 122 and the dispensing stage assembly 123 are respectively disposed on two opposite sides of the movable die bonding stage assembly 2. That is, portions of the first track 21 and the second track 22 within the dispensing area 12 are located between the first material stage 122 and the dispensing stage assembly 123. It is understood that such a configuration allows both the first material stage 122 and the dispensing stage assembly 123 to be as close as possible to the movable die bonding stage assembly 2, reducing a response time for material preparation and the dispensing operation, thereby improving overall work efficiency.

As shown in FIGS. 1, 5, and 6, the first track 21, the second track 22, and the third track 31 are spaced apart and parallel to each other. The first track 21 and the second track 22 are located on one side of the dispensing area 12 close to the loading area 13. The third track 31 is located on one side of the loading area 13 close to the dispensing area 12.

In the embodiment of the present disclosure, a certain distance is maintained between the three tracks (i.e., the first track 21, the second track 22, and the third track 31), which prevents mutual interference between the movable assemblies on different tracks and ensures independence and high efficiency of each process. A parallel arrangement of the first track 21, the second track 22, and the third track 31 simplifies a path planning for the second robotic arm 131 and other transport tools, reducing complexity and improving operational efficiency. Further, the parallel arrangement of the three tracks close to their respective areas ensures that a distance for moving each of the chips onto a corresponding substrate during a chip mounting process is shorter. A shorter moving distance means that the second robotic arm 131 or the transport tools are able to respond more quickly to operational commands, reducing waiting time and periodic delays. Furthermore, the shorter moving distance reduces deviations in chip mounting positions that may be caused by long-distance handling, thereby improving the accuracy of chip mounting, which is particularly important in semiconductor manufacturing processes with high precision requirements.

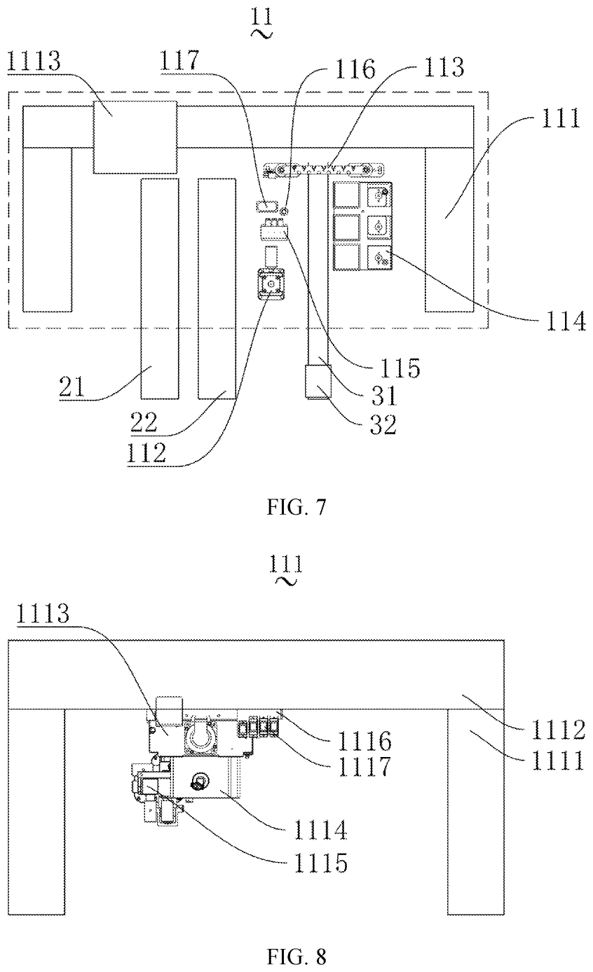

As shown in FIGS. 6-7, in one embodiment, a first upward-looking module 133 is disposed within the loading area 13, and a second upward-looking module 112 is disposed within the mounting area 11. The first upward-looking module 133 is located between the second material stage 132 and the third track 31. The second upward-looking module 112 is located between the third track 31 and the movable die bonding stage assembly 2. Shooting accuracy of the second upward-looking module 112 is greater than a shooting accuracy of the first upward-looking module 133.

In the embodiment of the present disclosure, by providing the first upward-looking module 133 and the second upward-looking module 112 to perform two calibrations of the chips during loading and mounting processes, it is ensured that each of the chips is accurately bonded to the corresponding substrate with high precision. Specifically, the first upward-looking module 133 is mainly configured to capture images when one of the chips is transferred from the second material stage 132 to the first transfer stage 32 on the third track 31, ensuring a basic orientation of each of the chips is correct and suitable for preliminary adjustment of a position of each of the chips. The second upward-looking module 112 is configured for high-precision imaging just before each of the chips is mounted onto the corresponding substrate to ensure a final position of each of the chips is precise and error-free. Due to the higher shooting accuracy of the second upward-looking module 112, the second upward-looking module 112 is able to capture finer positional deviations, thereby achieving more delicate adjustments. By first using the first upward-looking module 133 with a low precision for coarse calibration and then using the second upward-looking module 112 with a high precision for fine calibration, a process of gradually optimizing the position of each of the chips is realized. The step-by-step calibration method not only improves accuracy of calibration but also saves time, avoiding complexity and increased costs associated with one-time high-precision calibration.

In one embodiment, the first upward-looking module 133 and the second upward-looking module 112 are both upward-looking charge coupled devices (CCD). A CCD is a semiconductor device capable of converting optical images into digital signals to achieve operations such as image acquisition, storage, transmission, and processing.

As shown in FIG. 7, in one embodiment, a nozzle rack assembly 113 is disposed within the mounting area 11. The nozzle rack assembly 113 is located at one end of the third track 31 and spans above the third track 31.

In the embodiment of the present disclosure, the nozzle rack assembly 113 is allowed to be equipped with different types of nozzles, making it convenient for the main bonding head to replace nozzles to adapt to chips of various sizes and shapes, which enhances versatility and flexibility of the dual-track die bonding device 100. The nozzle rack assembly 113 is disposed at the end of the third track 31 and spans above the third track 31 so that a vertical space is fully utilized to prevent the nozzle rack assembly 113 from occupying additional horizontal area, making an overall layout of the dual-track die bonding device 100 compact. When a nozzle needs to be replaced, since the nozzle rack assembly 113 is already located at the end of the third track 31, the nozzle rack assembly 113 is able to immediately move to a position of the first transfer stage 32 after a replacement of the nozzle is completed without requiring additional long-distance movement, significantly shortening preparation time. Even in cases of frequent replacements of the nozzles, a short distance between the nozzle rack assembly 113 and the first transfer stage 32 ensures that a first picking operation performed by the nozzle rack assembly 113 after each replacement is completed quickly and accurately, guaranteeing the precision of chip mounting.

In one embodiment, a horizontal height of the nozzle rack assembly 113 is greater than a horizontal height of the first transfer stage 32. It is understood that the nozzle rack assembly 113 is higher than the first transfer stage 32, which ensures that the nozzle rack assembly 113 does not have physical contact or collision with the first transfer stage 32 during operation, especially when the nozzle rack assembly moves, picks, and places any one of the chips, the nozzle rack assembly has sufficient vertical space for moving to avoid potential operational interference.

In one embodiment, a third material stage 114 and a second transfer stage 115 are disposed within the mounting area 11. The third material stage 114 and the second transfer stage 115 are respectively disposed on two sides of the third track 31. The second transfer stage 115 is located between the third track 31 and the movable die bonding stage assembly 2. The second transfer stage 115 is close to the second upward-looking module 112.

In the embodiment of the present disclosure, the third material stage 114 serves as a storage and supply spot for multiple types of chips, providing a stable and sufficient supply of raw materials for the mounting process. The third material stage 114 is capable of supporting the chips of different specifications and quantities, adapting to diversified production requirements. The third material stage 114 and the second transfer stage 115 are respectively disposed on two sides of the third track 31, preventing crossover of material transfer paths and minimizing the distance from the first transfer stage 32 and the second transfer stage 115 to the movable die bonding stage assembly 2. Being disposed close to the second upward-looking module 112, the second transfer stage 115 allows for fine calibration under high-precision imaging, ensuring each of the chips is in the optimal position before entering a mounting step, thereby improving a success rate and quality of chip mounting.

In one embodiment, a standard positioning piece 116 is disposed within the mounting area 11. A top surface of the standard positioning piece 116 defines a positioning point. The standard positioning piece 116 is disposed between the third track 31 and the movable die bonding stage assembly 2.

In the embodiment of the present disclosure, the positioning point serves as a calibration reference for the main bonding head, providing a precise reference position. Through the positioning point on the standard positioning piece 116, high-precision calibration of the main bonding head and other related components is achieved, ensuring that each of the chips is accurately bonded to a designated position on the corresponding substrate, which greatly enhances the quality and reliability of chip mounting. The standard positioning piece 116 is located between two key components, fully utilizing the space within the mounting area 11 and avoiding an occupation of additional space, making the overall layout of the dual-track die bonding device 100 compact and reasonable.

As shown in FIGS. 7-8, in one embodiment, a gantry assembly 111 is disposed within the mounting area 11. The gantry assembly 111 comprises two support columns 1111 and a beam rail 1112. The two support columns 1111 are located on two opposite sides of the mounting area 11. The beam rail 1112 is slidably disposed between the two support columns 1111. A main bonding head 1113 is disposed on the beam rail 1112. A replaceable nozzle 1114 and a downward-looking module 1115 are disposed on the main bonding head 1113.

In the embodiment of the present disclosure, the two support columns 1111 provide a stable foundation for the gantry assembly 111, ensuring stability during operation and reducing vibrations caused by mechanical movement or external factors. The beam rail 1112 is slidable along the two support columns 1111, enabling the main bonding head 1113 to move freely within the mounting area 11, covering a larger workspace and adapting to the mounting requirements of substrates and chips of various specifications and positions. The main bonding head 1113 is slidable on the beam rail 1112, achieving flexible movement within the mounting area 11 and allowing it to quickly reach any required position for the chip mounting operation. The replaceable nozzle 1114 is configured to accurately pick and place each of the chips, ensuring each of the chips is precisely bonded to the designated position on the corresponding substrate. The downward-looking module 1115 is able to capture images of the position of each of the chips and each substrate in real-time during the mounting process, ensuring every chip is in the optimal position before each mounting action to prevent misalignment or offset. Through the stable support provided by the gantry assembly 111 and the high-precision visual detection of the downward-looking module 1115, the accuracy and consistency of each chip mounting operation are ensured, significantly improving mounting quality and reliability.

Optionally, an expansion component 1116 is disposed on the main bonding head. The expansion component 1116 comprises at least one expansion module 1117. The at least one expansion module 1117 comprises auxiliary bonding heads or a dispensing component.

In the embodiment of the present disclosure, the expansion component 1116 provides physical space and interfaces for adding additional components, allowing the dual-track die bonding device 100 to be flexibly configured according to actual production needs, which enhances versatility and adaptability of the dual-track die bonding device 100. The at least one expansion module 1117 is primarily configured to achieve multi-chip mounting, is capable of picking up a plurality of chips at once and accurately placing the plurality of chips onto designated positions on a corresponding substrate, significantly improving mounting efficiency. Since the at least one expansion module 1117 comprises nozzles of different specifications, a need for frequent replacement of the replaceable nozzle is reduced, saving time and costs while improving overall work efficiency.

In one embodiment, the at least one expansion module 1117 comprises auxiliary bonding heads or a dispensing component. It is understood that the auxiliary bonding heads are primarily configured to achieve synchronous mounting of the plurality of chips, capable of picking up the plurality of chips at once and accurately placing the plurality of chips onto designated positions on the corresponding substrate, which significantly improves mounting efficiency. Depending on the requirements of the chips with different specifications and shapes, different types of auxiliary bonding heads are equipped, enhancing a capability of the dual-track die bonding device to support various chip processing tasks. Since the auxiliary bonding heads are allowed to work simultaneously, a need for frequent replacements of the replaceable nozzle is reduced, saving time and costs while improving overall work efficiency. The dispensing component is configured to precisely control an amount of adhesive for each dispensing operation, ensuring an appropriate amount of adhesive required for each mounting process and avoiding problems caused by excessive or insufficient adhesive. The dispensing component makes the dispensing operation more centralized and efficient, reducing the time interval from dispensing to mounting and further improving production efficiency.

In one embodiment, the at least one expansion module 1117, by providing the auxiliary bonding heads, is able to transfer the plurality of chips from the first transfer stage 32 to the second transfer stage 115 at one time, and then allow the main bonding head 1113 to perform the chip mounting operation between the second transfer stage 115 and the die bonding stage. At this time, the unloaded first transfer stage 32 is returned to the loading area 13 in advance for a next round of loading.

A second embodiment of the present disclosure provides a die bonding method applied to the dual-track die bonding device 100 mentioned above. The die bonding method comprises:
performing, within the dispensing area 12, the dispensing operation on a substrate placed on the first die bonding stage 23 or a substrate placed on the second die bonding stage 24 via the first robotic arm, and transporting a dispensed substrate into the mounting area 11; where only a partial area of each substrate is dispensed each time the dispensing operation is performed;
transporting a chip onto the first transfer stage 32 via the second robotic arm 131 within the loading area 23, and moving the first transfer stage 32 to the mounting area 11 via the third track 31;
mounting the chip from the first transfer stage 32 alternately onto the dispensed substrate placed on the first die bonding stage 23 or the disposed substrate placed on the second die bonding stage 24 via the main bonding head within the mounting area 11 to complete chip mounting; and
performing at least two rounds of dispensing and chip mounting on each substrate by moving the movable die bonding stage assembly back and forth between the mounting area 11 and the dispensing area 12.

When the first die bonding stage 23 is located within the mounting area 11, and the second die bonding stage 24 is located within the dispensing area 12, and when the first die bonding stage 23 is located within the dispensing area 12, the second die bonding stage 24 is located within the mounting area 11, so that the dispensing operation and a chip mounting operation are performed synchronously on the first die bonding stage 23 and the second die bonding stage 24, respectively.

The embodiment of the present disclosure further provides the die bonding method applied to the aforementioned die bonding device, which therefore possesses the same effects as the dual-track die bonding device 100 described above, and is not reiterated herein.

As shown in FIGS. 1-8, a working process/principle of the dual-track die bonding device 100 provided in the embodiment of the present disclosure is briefly described as follows.

The dual-track die bonding device 100 mainly consists of the carrying platform 1, the movable die bonding stage assembly 2, the movable transfer stage assembly 3, robotic arms, vision modules, the nozzle rack assembly, and the gantry assembly 111.

The carrying platform 1 serves as a basic platform for the entire dual-track die bonding device. The carrying platform 1 defines the mounting area 11, the dispensing area 12, and the loading area 13.

The movable die bonding stage assembly 2 comprises the first track 21, the second track 22, the first die bonding stage 23, and the second die bonding stage 24. The movable die bonding stage assembly 2 is configured to work alternately between the dispensing area 12 and the mounting area 11.

The movable transfer stage assembly 3 comprises the third track 31 and the first transfer stage 32. The movable transfer stage assembly 3 is configured to transport the chips between the loading area 13 and the mounting area 11.

The robotic arms comprise the first robotic arm 121 disposed within the dispensing area 12 and the second robotic arm 131 disposed within the loading area 13. The first robotic arm 121 is responsible for material transportation and dispensing operation. The second robotic arm 131 is configured to transport the chips from the second material stage 132 to the first transfer stage 32.

The vision modules comprise the first upward-looking module 133 disposed within the loading area 13 and the second upward-looking module 112 with high precision disposed within the mounting area 11. The vision modules are configured to calibrate the chip positions.

The nozzle rack assembly is located above an end of the third track 31 and is capable of adapting to different types of nozzles for picking and placing the chips.

The gantry assembly 111 comprises the two support columns 1111, the beam rail 1112, and the main bonding head 1113. The gantry assembly 111 is configured to achieve high-precision chip mounting operation.

The mounting process is depicted as follows.

In the loading area 13, the second robotic arm 131 picks up a chip to be mounted from the second material stage 132 and places the chip to be mounted onto the first transfer stage 32. During this process, the first upward-looking module 133 performs a preliminary calibration on the chip to be mounted. The first transfer stage 32 slides to the mounting area 11 via the third track 31.

In the dispensing area 12, the first robotic arm 121 obtains adhesive from the dispensing stage assembly 123 and dips the adhesive onto a substrate on the first die bonding stage 23 or a substrate on the second die bonding stage 24. Only a partial area of a corresponding substrate is dispensed each time, and the corresponding substrate is then transported to the mounting area 11 to prevent the adhesive from solidifying during long waiting periods.

In the mounting area 11, the replaceable nozzle 1114 on the main bonding head 1113 picks up the chip to be mounted from the first transfer stage 32 and/or the third material stage 114 and accurately places the chip to be mounted onto a corresponding position of the substrate on the first die bonding stage 23 or the substrate on the second die bonding stage 24. During this process, the second upward-looking module 112 performs high-precision imaging on the chip to be mounted to ensure a final position of the chip to be mounted is precise and error-free.

The first die bonding stage 23 and the second die bonding stage 24 work alternately between the dispensing area 12 and the mounting area 11, and the chip to be mounted is immediately mounted on the corresponding substrate after each partial dispensing is completed, shortening the time interval from dispensing to mounting. Each substrate moves back and forth within the mounting area 11 and the dispensing area 12 via the movable die bonding stage assembly 2 to complete at least two rounds of dispensing and chip mounting (i.e., at least two chips are mounted on each substrate), ensuring that all chips are accurately bonded to the substrates.

The above embodiment of the present disclosure provides a detailed illustration of the dual-track die bonding device and the die bonding method. In the present disclosure, specific embodiments are applied to illustrate the principles and implementations of the present disclosure. The above description of the embodiments is only used to better understand methods and core ideas of the present disclosure. Meanwhile, according to the ideas of the present disclosure, changes are made in the specific implementations and the application scope by those skilled in the art. Therefore, the contents of the specification should not be regarded as a limitation of the present disclosure. Any modifications, equivalent substitutions, improvements, etc. made within the principles of the present disclosure shall be comprised within the protection scope of the present disclosure.

What is claimed is:

1. A dual-track die bonding device, comprising:
a carrying platform;
a movable die bonding stage assembly disposed on the carrying platform; and
a movable transfer stage assembly disposed on the carrying platform;
wherein the carrying platform defines a mounting area, a dispensing area, and a loading area, the dispensing area and the loading area are adjacent to each other, and the dispensing area and the loading area are defined on a same side of the mounting area;
wherein the movable die bonding stage assembly comprises a first track, a second track, a first die bonding stage, and a second die bonding stage, wherein the first die bonding stage is slidably connected to the first track, the second die bonding stage is slidably connected to the second track, and the first track and the second track respectively extend from the dispensing area to the mounting area;
wherein in a working state, the first die bonding stage and the second die bonding stage work alternately in the mounting area and the dispensing area;
wherein the movable transfer stage assembly comprises a third track and a first transfer stage slidably connected to the third track, the third track extends from the loading area to the mounting area, and the first transfer stage is movable back and forth between the loading area and the mounting area via the third track;
wherein a first robotic arm is disposed within the dispensing area, the first robotic arm is movable within the dispensing area, a second robotic arm is disposed within the loading area, and the second robotic arm is movable within the loading area;
wherein a main bonding head is disposed within the mounting area, and the main bonding head is configured to perform a chip mounting operation within the mounting area;
wherein the first robotic arm independently performs a dispensing operation within the dispensing area, the second robotic arm independently performs a loading operation within the loading area, and the main bonding head independently performs the chip mounting operation within the mounting area.

2. The dual-track die bonding device according to claim 1, wherein a first material stage and a dispensing stage assembly are disposed within the dispensing area;
wherein the first robotic arm is configured to transport first materials between the first material stage and the movable die bonding stage assembly, or perform the dispensing operation between the dispensing stage assembly and the movable die bonding stage assembly;
wherein a second material stage is disposed within the loading area, and when the first transfer stage is located within the loading area, the second robotic arm is configured to transport the second materials between the second material stage and the first transfer stage.

3. The dual-track die bonding device according to claim 2, wherein the first track, the second track, and the third track are spaced apart and parallel to each other; the first track and the second track are located on one side of the dispensing area close to the loading area, and the third track is located on one side of the loading area close to the dispensing area.

4. The dual-track die bonding device according to claim 3, wherein a first upward-looking module is disposed within the loading area, a second upward-looking module is disposed within the mounting area, the first upward-looking module is located between the second material stage and the third track, and the second upward-looking module is located between the third track and the movable die bonding stage assembly;
wherein a shooting accuracy of the second upward-looking module is greater than a shooting accuracy of the first upward-looking module.

5. The dual-track die bonding device according to claim 1, wherein a nozzle rack assembly is disposed within the mounting area, the nozzle rack assembly is located at one end of the third track and spans above the third track, a horizontal height of the nozzle rack assembly is greater than a horizontal height of the first transfer stage.

6. The dual-track die bonding device according to claim 4, wherein a third material stage and a second transfer stage are disposed within the mounting area, the third material stage and the second transfer stage are respectively disposed on two sides of the third track, the second transfer stage is located between the third track and the movable die bonding stage assembly, and the second transfer stage is close to the second upward-looking module.

7. The dual-track die bonding device according to claim 1, wherein a standard positioning piece is disposed within the mounting area, a top surface of the standard positioning piece defines a positioning point, the standard positioning piece is disposed between the third track and the movable die bonding stage assembly.

8. The dual-track die bonding device according to claim 1, wherein a gantry assembly is disposed within the mounting area, the gantry assembly comprises two support columns and a beam rail, the two support columns are located on two opposite sides of the mounting area, the beam rail is slidably disposed between the two support columns, the main bonding head is disposed on the beam rail, and a replaceable nozzle and a downward-looking module are disposed on the main bonding head.

9. The dual-track die bonding device according to claim 8, wherein an expansion component is disposed on the main bonding head, the expansion component comprises at least one expansion module, and the at least one expansion module comprises auxiliary bonding heads or a dispensing component.

10. A die bonding method, applied to the dual-track die bonding device according to claim 1, comprising:
performing, within the dispensing area, the dispensing operation on a substrate placed on the first die bonding stage or a substrate placed on the second die bonding stage via the first robotic arm, and transporting a dispensed substrate into the mounting area; wherein only a partial area of each substrate is dispensed each time the dispensing operation is performed;
transporting a chip onto the first transfer stage via the second robotic arm within the loading area, and moving the first transfer stage to the mounting area via the third track;
mounting the chip from the first transfer stage alternately onto the dispensed substrate placed on the first die bonding stage or the disposed substrate placed on the second die bonding stage via the main bonding head within the mounting area to complete chip mounting; and
performing at least two rounds of dispensing and chip mounting on each substrate by moving the movable die bonding stage assembly back and forth between the mounting area and the dispensing area;
wherein when the first die bonding stage is located within the mounting area, and the second die bonding stage is located within the dispensing area, and when the first die bonding stage is located within the dispensing area, the second die bonding stage is located within the mounting area, so that the dispensing operation and the chip mounting operation are performed synchronously on the first die bonding stage and the second die bonding stage, respectively.
